(19) United States
(12) Patent Application Publication
(10) Pub. No.: US 2010/0051932 A1
(43) Pub. Date: Mar. 4, 2010

(54) NANOSTRUCTURE AND USES THEREOF

(76) Inventor: Seo-Yong Cho, Seoul (KR)

Correspondence Address: Seo-Yong Cho, San 4-2, Bongchun-Dong, Gwanak-Gu, Seoul, 151-818, KR

(21) Appl. No.: 12/200,576

(22) Filed: Aug. 28, 2008

(51) Int. Cl. H01L 29/12; H01L 31/0256; H01L 21/20

(52) U.S. Cl. 257/43; 136/252; 438/478; 257/E29.068; 257/E21.09

(57) ABSTRACT

Disclosed herein are nanostructures comprising a conducting substrate, an array of nanowires, and one or more semiconductor nanolayers disposed radially around the nanowires. A layer of dye may be further disposed radially around the one or more semiconductor layers. The nanostructures may be used to provide a dye-sensitizing solar cell device. Other devices including the nanostructures and methods for making the nanostructures are also provided.

### BACKGROUND

One-dimensional nanostructures such as nanorods, nanowires and nanofibres exhibit a wide range of electrical and optical properties that depend on size and shape. Nanostructures including conductors and/or semiconductors may find use in electronics, optical and optoelectronic devices. Such devices include sensors, transistors, detectors, and light-emitting diodes.

### SUMMARY

In one embodiment, a nanostructure is provided comprising a conducting substrate, an array of nanowires extending from the conducting substrate, the nanowires comprising a conducting oxide, and a one or more semiconductor nanolayers disposed radially around the nanowires. The conducting substrate may comprise a metal or a metal oxide, and may also comprise a transparent conducting oxide (TCO). The nanowires may also comprise a transparent conducting oxide (TCO), which may be selected from the group consisting of SnO₂, CdO; ZnO, indium-tin-oxide (ITO), Al-doped zinc oxide (AZO), Zn-doped indium oxide (IZO), MgO, Nb:SrTiO₃, Ga-doped ZnO (GZO), Nb-doped TiO₂, (La_{0.5}Sr_{0.5})CoO₃ (LSCO), La_{0.7}Sr_{0.3}MnO₃ (LSMO), SrRuO₃ (SRO), F-doped tin-oxide (FTO), Sr₃Ru₂O₇; and Sr₄Ru₃O₁₀. The distance between adjacent nanowires may range from about 5 nm to about 200 nm, and the nanowires may have an aspect ratio of at least about 1. The semiconductor nanolayer may have a thickness of from about 5 nm to about 50 nm. The semiconductor nanolayer may comprise doped or undoped titanium oxide, metatitanic acid, orthotitanic acid, titanium hydroxide, zinc oxide, tungsten oxide, tin oxide, antimony oxide, niobium oxide, indium oxide, barium titanate, strontium titanate, or cadmium sulfide. The nanowires may comprise indium-tin-oxide (ITO), Nb:SrTiO₃, Al-doped ZnO (AZO), Zn-doped In₂O₃ (IZO), or F-doped tin-oxide (FTO). The nanostructure may further comprise a layer of dye disposed radially around the one or more semiconductor nanolayers. The dye may comprise one or more metal complexes or one or more organic dyes. The metal complexes may be selected from the group consisting of metal phthalocyanine, chlorophyll, hemin, ruthenium complex, osmium complex, iron complex or zinc complex. The organic dyes may be selected from the group consisting of metal-free phthalocyanine, cyanine dyes, merocyanine dyes, xanthene dyes and triphenylmethane dyes. The semiconductor nanolayers may comprise titanium oxide.

In one embodiment, a nanostructure is provided comprising a conducting substrate, an array of Sn-doped In₂O₃ nanowires extending from the conducting substrate, one or more TiO₂ semiconductor nanolayers disposed radially around the nanowires, and a layer of ruthenium complex dye disposed radially around the one or more semiconductor nanolayers. The device may comprise a nanostructure comprising a conducting substrate, an array of nanowires extending from the conducting substrate, the nanowires comprising a conducting oxide, and a one or more semiconductor nanolayers disposed radially around the nanowires. A photovoltaic device, a solar cell, or a photoelectrochemical device is also provided comprising a nanostructure comprising a conducting substrate, an array of nanowires extending from the conducting substrate, the nanowires comprising a conducting oxide, and a one or more semiconductor nanolayers disposed radially around the nanowires. The photochemical electro device may be configured for the electrolysis of water to produce hydrogen. A dye-sensitized photoelectrode is also provided comprising a nanostructure comprising a conducting substrate, an array of nanowires extending from the conducting substrate, the nanowires comprising a conducting oxide, and a one or more semiconductor nanolayers disposed radially around the nanowires, and further comprising a layer of dye disposed radially around the one or more semiconductor nanolayers. A dye-sensitized solar cell is also provided comprising the dye-sensitized photoelectrode described above.

In another embodiment, a method for forming a nanostructure is provided, comprising forming an array of nanowires extending from a conducting substrate, and forming one or more semiconductor nanolayers disposed radially around the nanowires. The method may further comprise forming a layer of dye disposed radially around the one or more semiconductor nanolayers.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 depicts an illustrative embodiment of a nanostructure, a photoelectrode device incorporating the nanostructure, and a dye-sensitized solar cell (DSSC) incorporating the photoelectrode.

### DETAILED DESCRIPTION

In the following detailed description, reference is made to the accompanying drawings, which forms a part hereof. In the drawings, similar symbols typically identify similar components, unless context dictates otherwise. The illustrative embodiments described in the detailed description, drawing, and claims are not meant to be limiting. Other embodiments may be utilized, and other changes may be made, without departing from the spirit or scope of the subject matter presented here.

The present technology relates to nanostructures, devices incorporating the nanostructures, and related methods. The nanostructures include a conducting substrate, an array of nanowires, and one or more semiconductor nanolayers disposed radially around the nanowires. A layer of dye may be further disposed radially around the one or more semiconductor layers. The nanostructures may be used to provide dye-sensitized solar cells (DSSCs) that are more efficient than conventional DSSCs.

The nanostructures disclosed herein comprise a conducting substrate. A variety of substrate materials may be used provided the substrate material is conducting. Examples of conducting substrates include, but are not limited to, e.g., metals such as copper, titanium and stainless steel, and metal oxides including transparent metal oxide such as SnO₂, CdO, ZnO, indium-tin-oxide (ITO), F:SnO₂ (FTO), Al-doped zinc oxide (AZO), Zn-doped indium oxide (IZO), Ga-doped indium oxide (GZO), Nb:SrTiO₂, sapphire, Nb:TiO₂, (La_{0.5}Sr_{0.5})CoO₃ (LSCO), La_{0.7}Sr_{0.3}MnO₃ (LSMO), SrRuO₃ (SRO), Sr₃Ru₂O₇, Sr₄Ru₃O₁₀, and the like.

The nanostructures disclosed herein further comprise an array of nanowires extending from the conducting substrate. The nanowires may be substantially perpendicular to the surface of the substrate. By substantially perpendicular it is meant that the longitudinal axis of the nanowires forms an approximate right angle with the substrate surface. However, the longitudinal axis of the nanowires may form angles with the surface of the substrate that are less than or greater than 90°. The nanowires disclosed herein are formed from a conducting oxide. In one embodiment, the nanowires comprise a transparent conducting oxide (TCO). A variety of transparent conducting oxides may be used to form the nanowires, including, but not limited to, e.g., In₂O₃, SnO₂, CdO, ZnO, indium-tin-oxide (ITO), F-doped In₂O₃, Al-doped ZnO (AZO), Zn-doped In₂O₃ (IZO), Sb-doped SnO₂, F-doped SnO₂, F-doped ZnO, MgO, Nb:SrTiO₃, Ga-doped ZnO (GZO), Nb-doped TiO₂, (La_{0.5}Sr_{0.5})CoO₃ (LSCO), La_{0.7}Sr_{0.3}MnO₃ (LSMO), SrRuO₃ (SRO), Sr₃Ru₂O₇, and Sr₄Ru₃O₁₀.

The dimensions of the nanowires may vary. The distance between adjacent nanowires may also vary. The term “distance” between nanowires as used herein refers to center-to-center distance unless otherwise stated, and may range from about 5 nm to about 200 nm. Similarly, the aspect ratio (the ratio of the long dimension to the short dimension) of the nanowires may vary. In some embodiments, the nanowires have an aspect ratio of at least about 1. The aspect ratio as used herein is to describe the dimensions of the nanowires. When the aspect ratio is 1, the shape of nanowires may be cubic, while when the aspect ratio is more than 1, the shape of nanowires may be wire form.

Nanowires may be formed by a variety of well-known techniques, including, but not limited to, vapor phase deposition, oxidation of metallic nanorods, vapor-liquid-solid (VLS) growth under vacuum, seeded growth, and template filling of oxide colloidal particles, sol electrophoretic deposition, and the like. Such methods are disclosed in J. Phys. Chem. B 2004, 108, 19921-19931 and references therein, Adv. Mater. 2006, 18, 234-238, Nature Materials 2005, 4, 455-459, and the like. The Sn-doped In₂O₃ nanowires can be provided on the substrate by using known methods of fabricating oxide nanorods in the art, for example, vapor phase deposition, oxidation of metallic nanorods, vapor-liquid-solid (VLS) growth under vacuum, seeded growth, and template filling of oxide colloidal particles, sol electrophoretic deposition, and the like. For example, the nanowires of Sn-doped In₂O₃ may be prepared by self-catalytic VLS growth as disclosed in J. Phys. D: Appl. Phys. 37 (2004) 3319-3322 and references therein; low temperature synthesis as disclosed in Nanotechnology 16 (2005) 451-457 and references therein; and sol electrophoretic deposition disclosed in J. Phys. Chem. B 2004, 108, 19921-19931 and references therein.

The nanostructures disclosed herein further comprise one or more semiconductor nanolayers disposed radially around the nanowires. A variety of semiconductor materials may be used to form the nanolayers. In some embodiments, the semiconductor nanolayer comprises doped or undoped titanium oxide, metatitanic acid, orthotitanic acid, titanium hydroxide, zinc oxide, tungsten oxide, tin oxide, antimony oxide, niobium oxide, indium oxide, barium titanate, strontium titanate, or cadmium sulfide. The form of the titanium oxide may vary. In some embodiments, the titanium oxide comprises anatase-form titanium oxide, rutile-form titanium oxide, amorphous titanium oxide, hydrated titanium oxide, or combinations thereof.

The thickness of the semiconductor nanolayers may vary. By way of example only, the thickness may range from about 5 nm to about 50 nm, or from about 5 nm to about 10 nm. When the thickness is more than 50 nm, the light transmission efficiency may be reduced. The semiconductor nanolayers on the nanowaves may form a continuous sheath around the nanowires for charge transfer.

A variety of well-known techniques may be used to form the semiconductor nanolayers on the nanowires, including, but not limited to methods of forming thin films such as chemical vapor deposition (CVD) or atomic layer deposition (ALD). CVD or ALD methods are described, for instance, in Chemical Vapor Deposition, Vol. 10 issue 3, 2004, p 143-148. TiO₂ semiconductor nanolayer may be deposited on the nanowires by ALD at 200-400° C. from titanium precursor, titanium tetramethoxide, and water.

The nanostructures may further comprise a layer of dye disposed radially around the one or more semiconductor nanolayers. In some embodiments, the dye is adsorbed on the surface of the semiconductor nanolayer.

A variety of dyes may be used. In some embodiments, the dye is capable of absorbing visible light, infrared light, or both. In further embodiments, the dye comprises one or more metal complexes or one or more organic dyes. Non-limiting examples of metal complexes and organic dyes include those disclosed in U.S. Pat. No. 7,118,936 B2. Other non-limiting examples of the metal complexes include metal phthalocyanine, such as copper phthalocyanine and titanyl phthalocyanine, chlorophyll, hemin, ruthenium complex, such as ruthenium complex having a dipyridophenazine or tetrapyridophenazine ligand, osmium complex, such as osmium complex having tetradentate polypyridine ligand, iron complex, such as iron complex having tetradentate polypyridine ligand and zinc complex, such as zinc complex having tetradentate polypyridine ligand, as described in JP-A-01-220380 and JP-A-05-504023. Other non-limiting examples of organic dyes include metal-free phthalocyanine, cyanine dyes, merocyanine dyes, xanthene dyes and triphenylmethane dyes.

A variety of methods may be used to form a layer of dye disposed radially around the disclosed semiconductor nanolayers. In one embodiment, any of the disclosed nanostructures are dipped into a solution comprising the dye and an organic solvent at room temperature or under heating. Any solvent can be used, provided the dye is dissolved in the solvent. Non-limiting examples of the solvent include water, alcohol, toluene and dimethylformamide. As further described below, the nanostructure comprising a dye-sensitized semiconductor nanolayer (i.e., the semiconductor nanolayer surrounded by the layer of dye) can provide a photoelectrode for photoelectric conversion in photovoltaic device or dye-sensitized solar cell.

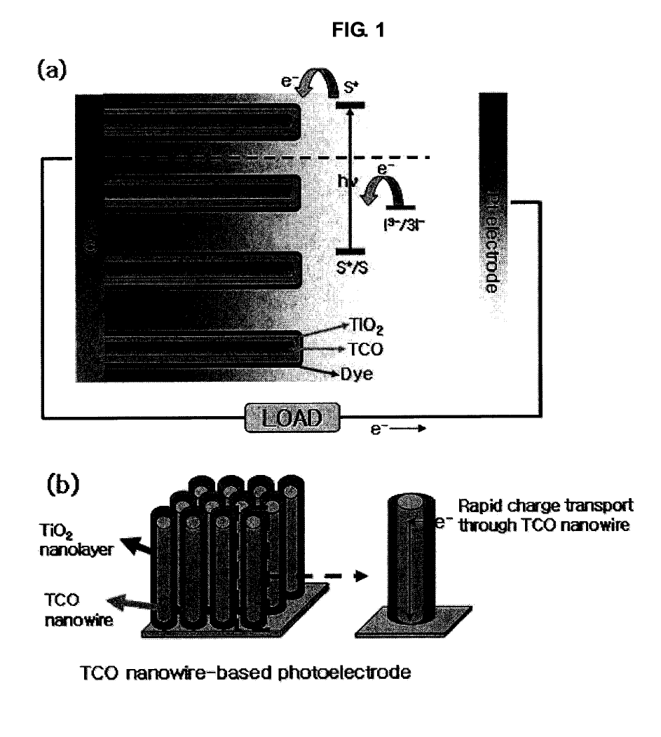

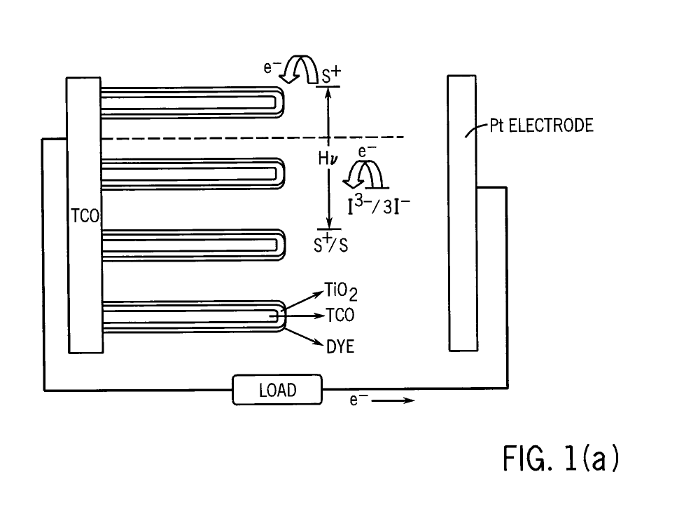

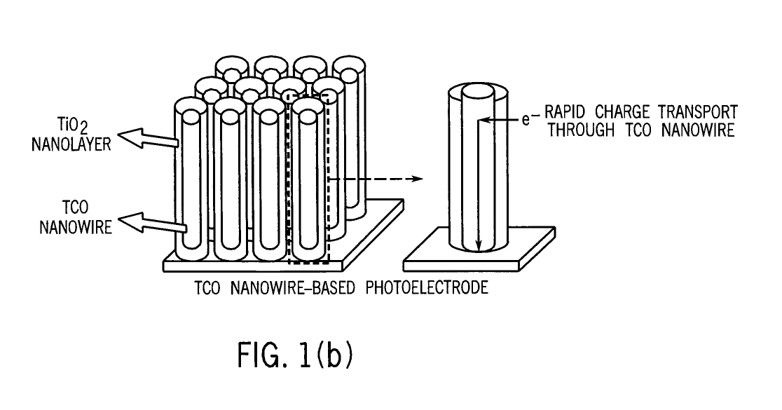

Also provided are devices comprising any of the nanostructures disclosed herein, including, but not limited to an electronic device, an optical device, an electro-optic device, and the like. In some embodiments, the device is a photoelectrode. When the nanostructure comprises a layer of dye, as disclosed above, the photoelectrode comprising the nanostructure provides a dye-sensitized photoelectrode. The photoelectrode comprising the nanostructure according to the present disclosure can be fabricated by known methods in the art, for example, by the method in U.S. Pat. No. 7,118,936 B2 and references therein. The photoelectrode may comprise conducting substrate (TCO), semiconductor layer, dye, electrolyte and Pt electrode as described in FIG. 1.

In other embodiments, the devices are a photovoltaic device, a solar cell, or a photoelectrochemical device comprising any of the photoelectrodes disclosed herein.

When the photoelectrode is a dye-sensitized photoelectrode, the resulting device is a dye-sensitized solar cell. Solar cells can be fabricated by using known methods in the art as disclosed, for example, in U.S. Pat. No. 7,118,936 B2, Nature Materials 2005, 4, 455-459 and references therein. The photoelectrochemical devices disclosed herein may be used for electrolysis of water to produce hydrogen, and may comprise TiO₂ semiconductor deposited on conducting substrate, Pt counter electrode, electrolyte.

As described above, the present technology provides dye-sensitized photoelectrodes and dye-sensitized solar cells. Conventional dye-sensitized solar cells suffer from poor efficiency. In particular, the efficiency of some such solar cells plateaus at 11-12% and is associated with inefficient charge transfer in TiO₂ nanoparticle-based photoelectrodes. By contrast, the disclosed dye-sensitized solar cells are much more efficient. In particular, the semiconductor nanolayer disposed radially around the nanowires, and the layer of dye disposed radially around the semiconductor nanolayer, provide a very large surface area for the absorption of light. The large surface area enhances the efficiency of light energy conversion. In addition, the one-dimensional aligned nanowires reduce grain boundaries between nanocrystals compared to conventional planar DSSCs deposited with TiO₂ nanoparticles. The grain boundaries between nanoparticles in conventional planar DSSCs tend to decrease the electric conductivity of the material because of charge recombination. However, the nanowires disclosed herein have same crystalline structure so that the grain boundaries are absent, thereby enhancing energy conversion efficiency.

Also provided are methods for forming any of the nanostructures disclosed herein. The nanostructure according to the present disclosure can be obtained by a method comprising forming an array of nanowires extending from a conducting substrate and forming one or more semiconductor nanolayers disposed radially around the nanowires. In one embodiment, the semiconductor nanolayer may be formed by chemical vapor deposition (CVD) or atomic layer deposition (ALD). In other embodiment, the method further comprises forming a layer of dye disposed radially around the one or more semiconductor nanolayers.

FIG. 1 depicts an illustrative embodiment of a nanostructure, a photoelectrode device incorporating the nanostructure, and a dye-sensitized solar cell (DSSC) incorporating the photoelectrode: (a) the 1-D TCO based photoelectrode contains TCO nanowires coated with TiO₂ nanolayers; (b) the employment of 1-D TCO-based photoelectrode enhances charge transport because of absence of grain boundaries between nanocrystals.

When a sensitizing dye adsorbed on the semiconductor layer is exposed to light, the dye absorbs light in visible region. Electrons generated by the excitation are transferred to the semiconductor layer and reduce an oxidation-reduction system in the electrolyte. The dye from which the electrons originate becomes oxidized. Thereafter the oxidized form is reduced by the oxidation-reduction system in the electrolyte, and thus returned to the original state. In this way, the electrons move in a stream, and the solar cell using the photoelectrode according to the present disclosure fulfills its function.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

The present embodiments, thus generally described, will be understood more readily by reference to the following examples, which are provided by way of illustration and are not intended to be limiting of the present technology in any way.

### EXAMPLES

The present technology is further illustrated by the following examples, which should not be construed as limiting in any way.

### Example 1

### Formation of a Nanostructure

A nanostructure comprising a conducting substrate, Sn-doped In₂O₃ nanowires extending from the substrate, and a TiO₂ semiconductor nanolayer disposed radially on the nanowires is formed. The nanowires of Sn-doped In₂O₃ are provided on the conducting substrate by self-catalytic VLS growth as disclosed in J. Phys. D:Appl. Phys. 37 (2004) 3319-3322 and references therein, in which In powder and SnO powder are thoroughly mixed (weight ratio In to SnO=9:1) and put into an alumina boat, which is inserted into a one-end-sealed quartz tube (radius=2 cm, length=20 cm). The quartz tube is then loaded into the center of the alumina tube of the furnace. Afterwards, the furnace is heated up to 920° C. and kept so for 20 min. After cooling down, a fluffy yellowish-green layer of deposition is collected from both the end the outer wall of the alumina boat. The crystal structure of the as-synthesized product is analyzed by X-ray diffraction and a high-resolution transmission electron microscope (HRTEM). Next, the TiO₂ semiconductor nanolayer is provided on the nanowires using the CVD process with the methods and devices for forming such a coating are described for example in French patent No 2348166 or in French patent application No 2648453. The TiO₂ semiconductor nanolayer on the nanowires is provided by CVD using a vaporized reactant of TTIP as titanium precursor. The deposition was performed using the TTIP in the deposition temperature ranging from about 200° C. to about 500° C. using Ar as a carrier gas and diluting gas, and O₂ as a reactant gas.

### Example 2

### Formation of a Nanostructure having a Layer of Dye

A nanostructure comprising a conducting substrate, Sn-doped In₂O₃ nanowires extending from the substrate, a TiO₂ semiconductor nanolayer disposed radially around the nanowires, and a layer of Ru complex dye disposed radially around the semiconductor nanolayer is formed. The nanostructure prepared as described in Example 1 is dipped into a solution of a Ru complex dye for adsorption on the TiO₂ semiconductor nanolayer. The dye adsorption is characterized by a UV-Visible and IR absorption spectroscopy.

### Equivalents

The present disclosure is not to be limited in terms of the particular embodiments described in this application. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A nanostructure comprising:
a conducting substrate;
an array of nanowires extending from the conducting substrate, the nanowires comprising a conducting oxide; and
a one or more semiconductor nanolayers disposed radially around the nanowires.

2. The nanostructure of claim 1, wherein the conducting substrate comprises a metal or a metal oxide.

3. The nanostructure of claim 1, wherein the conducting substrate comprises a transparent conducting oxide (TCO).

4. The nanostructure of claim 1, wherein the nanowires comprise a transparent conducting oxide (TCO).

5. The nanostructure of claim 4, wherein the transparent conducting oxide (TCO) is selected from the group consisting of SnO₂, CdO, ZnO, indium-tin-oxide (ITO), Al-doped zinc oxide (AZO), Zn-doped indium oxide (IZO), MgO, Nb:SrTiO₃, Ga-doped ZnO (GZO), Nb-doped TiO₂, (La_{0.5}Sr_{0.5})CoO₃ (LSCO), La_{0.7}Sr_{0.3}MnO₃ (LSMO), SrRuO₃ (SRO), F-doped tin-oxide (FTO), Sr₃Ru₂O₇, and Sr₄Ru₃O₁₀.

6. The nanostructure of claim 1, wherein the distance between adjacent nanowires ranges from about 5 nm to about 200 nm.

7. The nanostructure of claim 1, wherein the nanowires have an aspect ratio of at least about 1.

8. The nanostructure according to claim 1, wherein the semiconductor nanolayer has a thickness of from about 5 nm to about 50 nm.

9. The nanostructure of claim 1, wherein the semiconductor nanolayer comprises doped or undoped titanium oxide, metatitanic acid, orthotitanic acid, titanium hydroxide, zinc oxide, tungsten oxide, tin oxide, antimony oxide, niobium oxide, indium oxide, barium titanate, strontium titanate, or cadmium sulfide.

10. The nanostructure of claim 9, wherein the nanowires comprise indium-tin-oxide (ITO).

11. The nanostructure of claim 9, wherein the nanowires comprise Nb:SrTiO₃.

12. The nanostructure of claim 9, wherein the nanowires comprise Al-doped ZnO (AZO).

13. The nanostructure of claim 9, wherein the nanowires comprise Zn-doped In₂O₃ (IZO).

14. The nanostructure of claim 9, wherein the nanowires comprise F-doped tin-oxide (FTO).

15. The nanostructure of claim 1, further comprising a layer of dye disposed radially around the one or more semiconductor nanolayers.

16. The nanostructure of claim 15, wherein the dye comprises one or more metal complexes or one or more organic dyes.

17. The nanostructure of claim 16, wherein the one or more metal complexes are selected from the group consisting of metal phthalocyanine, chlorophyll, hemin, ruthenium complex, osmium complex, iron complex or zinc complex.

18. The nanostructure of claim 16, wherein the one or more organic dyes are selected from the group consisting of metal-free phthalocyanine, cyanine dyes, merocyanine dyes, xanthene dyes and triphenylmethane dyes.

19. The nanostructure of claim 15, wherein the one or more semiconductor nanolayers comprise titanium oxide.

20. A nanostructure comprising:
a conducting substrate;
an array of Sn-doped In₂O₃ nanowires extending from the conducting substrate;
one or more TiO₂ semiconductor nanolayers disposed radially around the nanowires; and
a layer of ruthenium complex dye disposed radially around the one or more semiconductor nanolayers.

21. A device comprising the nanostructure according to claim 1.

22. A photoelectrode comprising the nanostructure according to claim 1.

23. A photovoltaic device, a solar cell, or a photoelectrochemical device comprising the photoelectrode according to claim 22.

24. A photoelectrochemical device comprising the photoelectrode according to claim 22, wherein the photoelectrochemical device is configured for the electrolysis of water to produce hydrogen.

25. A dye-sensitized photoelectrode comprising the nanostructure according to claim 15.

26. A dye-sensitized solar cell comprising the dye-sensitized photoelectrode according to claim 25.

27. A method for forming a nanostructure, comprising:
forming an array of nanowires extending from a conducting substrate; and
forming one or more semiconductor nanolayers disposed radially around the nanowires.

28. The method of claim 27, further comprising forming a layer of dye disposed radially around the one or more semiconductor nanolayers.
